(19) United States
(12) Patent Application Publication
(10) Pub. No.: US 2009/0283794 A1
(43) Pub. Date: Nov. 19, 2009

(54) CURABLE RESIN MATERIAL COMPOSITION, OPTICAL MATERIAL, LIGHT-EMITTING DEVICE, METHOD FOR PRODUCING LIGHT-EMITTING DEVICE, AND ELECTRONIC DEVICE

(75) Inventors: Makihisa Mizuno, Miyagi (JP); Sungkil Lee, Miyagi (JP)

Correspondence Address: K&L Gates LLP, P. O. BOX 1135, CHICAGO, IL, 60690, US

(73) Assignee: SONY CORPORATION, Tokyo (JP)

(21) Appl. No.: 12/466,020

(22) Filed: May 14, 2009

(30) Foreign Application Priority Data
May 19, 2008 (JP) P2008-130444

(51) Int. Cl. H01L 33/00; C09K 11/02; H01J 9/22

(52) U.S. Cl. 257/100; 524/261; 156/67; 257/E33.059

(57) ABSTRACT

A curable resin material composition includes an addition-polymerization-curable silicone resin material that gives a silicone resin having a glass transition temperature of 50° C. or less when cured, the addition-polymerization-curable silicone resin material including, a SiH-group-containing siloxane-based compound containing a SiH group where a silicon atom is bonded to a hydrogen atom, a C═C-bond-containing siloxane-based compound containing a carbon-carbon double bond capable of effecting addition reaction with the SiH group, and a hydrosilylation addition reaction catalyst; and a non-reactive siloxane-based compound that does not react with the SiH-group-containing siloxane-based compound or the C═C-bond-containing siloxane-based compound, that is compatible with the addition-polymerization-curable silicone resin material, and that has a pour point of 0° C. or less.

### CROSS REFERENCES TO RELATED APPLICATIONS

The present application claims priority to Japanese Priority Patent Application JP 2008-130444 filed in the Japan Patent Office on May 19, 2008, the entire content of which is hereby incorporated by reference.

### BACKGROUND

The present application relates to a curable resin material composition, an optical material including a cured product of such a curable resin material composition, a light-emitting device including such an optical material, a method for producing such a light-emitting device, and an electronic device.

In recent years, there has been a growing trend toward use of optical materials composed of organic polymeric resins (hereinafter, referred to as organic optical resins) as materials for general optical parts such as lenses and optically transparent films and precision optical parts used for optoelectronics. Several reasons for this trend are that organic optical resins are lighter, less expensive, more durable, have better workability and are more suitable for mass production than inorganic optical materials.

For example, organic optical resins are used as sealing members for light-emitting devices equipped with light-emitting elements such as light-emitting diodes (LEDs) and laser diodes (LDs). Such light-emitting devices are small in size, but, emit light of high intensity. For this reason, these light-emitting devices are used in various applications such as stop lights of automobiles, signal lights, and large outdoor displays. Such light-emitting devices consume less power and have a long service life and hence these devices have also recently been used as, for example, backlight sources of liquid crystal displays for cellular phones and large liquid crystal television displays.

FIG. 5 is a section view showing an example of the general configuration of the light-emitting devices described above. A light-emitting device 100 includes a reflective cup 11 having a recess 12, a light-emitting element 13 disposed in the recess 12, and a sealing member 114 provided to be in contact with the light-emitting element 13 and to fill the recess 12. Light emitted from the light-emitting element 13 passes through the interface between the light-emitting element 13 and the sealing member 114, then through the sealing member 114, and reaches the outside of the light-emitting device 100 directly or as a result of reflection at a wall of the reflective cup 11.

The sealing member 114 is provided for the purpose of, for example, preventing the light-emitting element 13 and wires from coming into a direct contact with oxygen or moisture in the air or other corrosive gases, or preventing the light-emitting element 13 from being physically damaged by external forces. The sealing member 114 is provided to have an appropriate shape and an appropriate thickness in accordance with the purpose of placing the light-emitting device 100. For example, a typical LED includes the sealing member 114 having the shape shown in FIG. 5 and an appropriate thickness on or above the light-emitting element 13.

The sealing member 114 has been formed of one type of organic optical resins, that is, epoxy resins of glycidyl ether of bisphenol A. However, these resins do not have sufficient heat resistance and light resistance, in particular, resistance to ultraviolet (UV) light and blue light. For this reason, such resins used in LEDs such as high-intensity LEDs and UV-emitting LEDs are discolored by heat or light emitted from the LEDs and hence the intensity of light emitted from the LEDs varies over time. To overcome this problem, attempts have been made to develop a high-transparency epoxy resin, however, there is still no epoxy resin having sufficient heat resistance and light resistance.

Under these circumstances, silicone resins curable by addition polymerization (hereinafter, referred to as addition-polymerization-curable silicone resins; see Japanese Unexamined Patent Application Publication No. 11-1619, p. 2-5, and No. 2004-186168, p. 3-6) have been used as sealing materials for high-intensity LEDs instead of the epoxy resins. These silicone resins have better heat resistance and light resistance than the epoxy resins. Such an addition-polymerization-curable silicone resin material at least contains a SiH-group-containing siloxane-based compound containing a silicon atom bonded to a hydrogen atom, that is, a SiH group; a C═C-bond-containing siloxane-based compound containing a carbon-carbon double bond (C═C bond) that can effect addition reaction with the SiH group; and a hydrosilylation reaction catalyst in an effective amount.

Such an addition-polymerization-curable silicone resin material is cured by polymerizing a SiH-group-containing siloxane-based compound and a C═C-bond-containing siloxane-based compound by a hydrosilylation addition reaction. The hydrosilylation addition reaction proceeds as shown in the following reaction formula (1): the SiH group is added to the two carbon atoms forming the carbon-carbon double bond (C═C bond) and, as a result, one of the carbon atoms becomes bonded to the hydrogen atom and the other carbon atom becomes bonded to the silicon atom.

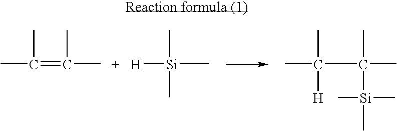

### SUMMARY

However, silicone resins have the following drawbacks.

First, when LEDs sealed with silicone resins are subjected to repeated damaging temperature cycles of high temperature while the LEDs are turned on and low temperature while the LEDs are turned off, thermal stress can cause failures such as generation of cracks in the resins, separation of the resins from chips, and disconnection of wires caused by the resins. For this reason, the range of applications in which silicone resins are used is limited.

Second, silicone resins have lower indices of refraction than epoxy resins and hence provide lower efficiency of outputting light from LEDs than epoxy resins. Specifically, high-intensity LEDs often include sapphire substrates as the chip substrates and light is typically output from the side of such sapphire substrates. For the purpose of efficiently introducing light emitted from a high-intensity LED to the sealing-member-114 side without causing total reflection of the light at the interface between a sapphire substrate and the sealing member 114, the sealing member 114 preferably has an index of refraction close to 1.76, which is the index of refraction of a sapphire substrate. However, a dimethyl silicone resin, which is a typical silicone resin, has an index of refraction of 1.41. This is lower than 1.53 to 1.57, which is the range of indices of refraction of epoxy resins. For this reason, use of a dimethyl silicone resin as a material for forming the sealing member 114 for high-intensity LEDs inevitably results in lower light-output efficiency than in the case of using epoxy resins.

Measures for overcoming the second drawback have been proposed. Such measures include a method of increasing the index of refraction of a silicone resin by introducing an aromatic ring such as a phenyl group into the resin; and a method of increasing the index of refraction of a resin composition by adding inorganic fine particles having a high index of refraction (fine particles of titanium oxide, zirconium oxide, or the like) into a silicone resin. However, no measures for overcoming the first drawback have yet been proposed.

It is desirable to provide a curable resin material composition with which a cured product having good resistance (thermal shock resistance) to repeated rapid temperature changes can be obtained, an optical material including a cured product obtained by curing such a curable resin material composition, a light-emitting device including such an optical material, a method for producing such a light-emitting device, and an electronic device.

An embodiment of the present application relates to a curable resin material composition including

an addition-polymerization-curable silicone resin material that gives a silicone resin having a glass transition temperature of 50° C. or less when cured, the addition-polymerization-curable silicone resin material including,

a SiH-group-containing siloxane-based compound containing a SiH group where a silicon atom is bonded to a hydrogen atom,

a C═C-bond-containing siloxane-based compound containing a carbon-carbon double bond capable of effecting addition reaction with the SiH group, and

a hydrosilylation addition reaction catalyst; and

a non-reactive siloxane-based compound that does not react with the SiH-group-containing siloxane-based compound or the C═C-bond-containing siloxane-based compound, that is compatible with the addition-polymerization-curable silicone resin material, and that has a pour point of 0° C. or less.

Another embodiment relates to an optical material including a cured product obtained by curing the above-mentioned curable resin material composition by addition polymerization reaction. Another embodiment relates to a light-emitting device configured to output, through the above-mentioned optical material, light emitted from a light-emitting element. Another embodiment relates to a method for producing a light-emitting device including the steps of: mounting a light-emitting element on a substrate; providing the above-mentioned curable resin material composition on the substrate to cover the light-emitting element; and curing the curable resin material composition to provide a cured product and to seal the light-emitting element with the cured product.

Another embodiment relates to an electronic device including an electronic element, and a cured product obtained by curing the above-mentioned curable resin material composition, wherein the electronic element is sealed with the cured product.

A curable resin material composition according to an embodiment includes the above-mentioned addition-polymerization-curable silicone resin material including the above-mentioned SiH-group-containing siloxane-based compound and the above-mentioned C═C-bond-containing siloxane-based compound, and the above-mentioned non-reactive siloxane-based compound that does not react with the SiH-group-containing siloxane-based compound or the C═C-bond-containing siloxane-based compound. This non-reactive siloxane-based compound is compatible with and uniformly mixes with the addition-polymerization-curable silicone resin material. Thus, a curable resin material composition and its cured product according to an embodiment are transparent.

When the addition-polymerization-curable silicone resin material is polymerized by an addition polymerization reaction, the non-reactive siloxane-based compound is not involved in the reaction and not introduced into the resultant polymer chains. Thus, the non-reactive siloxane-based compound imparts flexibility to the resultant cured product. As a result, this cured product has flexibility over a wide temperature range and relieves thermal stress caused by, for example, the difference between coefficients of thermal expansion with temperature variation.

The inventors of the present application have performed studies and have found that a cured product obtained by curing the above-mentioned addition-polymerization-curable silicone resin material alone has such a flexibility that disconnection of wires is not caused in the temperature range of a thermal shock test (−40° C. to 120° C.) when the glass transition temperature of the cured product is less than −40° C. There are elastomeric phenyl-group-containing addition-polymerization-curable silicone resin materials having an index of refraction of 1.50 or more whose cured products have a glass transition temperature of about 20° C. or less (addition-polymerization-curable silicone resin materials used in Examples). However, it is difficult to provide such a silicone resin material whose cured product has a glass transition temperature of less than −40° C.

However, it has been found that, when a curable resin material composition according to an embodiment contains the above-mentioned non-reactive siloxane-based compound that has a lower pour point, the cured product of the composition has better thermal shock resistance. In this case, it is more preferable that a cured product of the above-mentioned addition-polymerization-curable silicone resin material has a lower glass transition temperature. Specifically, when a cured product of the addition-polymerization-curable silicone resin material alone has a glass transition temperature of 50° C. or less, addition of the non-reactive siloxane-based compound having a pour point of 0° C. or less can decrease the glass transition temperature of the cured product to 20° C. or less without degrading other characteristics. When the cured product obtained by curing the above-mentioned composition has a glass transition temperature of not −40° C. or less but 20° C. or less, good thermal shock resistance can be obtained. The mechanism responsible for this is not determined, however, the non-reactive siloxane-based compound, which does not become cured, presumably imparts suitable flexibility to the cured product. The pour point is measured in accordance with JIS K2269.

An optical material according to an embodiment includes such a cured product. Thus, for example, in an LED light-emitting device in which a light-emitting diode chip is sealed with such an optical material, the optical material can flexibly deform to absorb stress caused by temperature changes. As a result, the optical material does not apply thermal stress to a light-emitting element and the wires of the light-emitting element even when subjected to repeated rapid temperature changes. Thus, the optical material does not cause a failure such as separating from the light-emitting element, damaging the light-emitting element, or causing disconnection of the wires and the optical material has excellent thermal shock resistance. In this case, degradation of the light-emitting element caused by sealing failure does not occur.

The above-mentioned cured product has a property of shape retention. Thus, in addition to providing sealing, the optical material can serve as a lens. The cured product also has excellent heat resistance and light resistance and thus maintains its transparency. As a result, when the optical material is used as a sealing member for a high-intensity LED, variation in intensity or tone of light emitted from the LED over time can be reduced.

A light-emitting device according to an embodiment is configured to output, through an optical material according to an embodiment, light emitted from a light-emitting element. Thus, a light-emitting device according to an embodiment has high reliability and good light-output efficiency. A method for producing a light-emitting device according to an embodiment includes the steps of providing the above-mentioned curable resin material composition and curing this composition. Thus, use of this method can provide with certainty a light-emitting device according to an embodiment.

A cured product of a curable resin material composition according to an embodiment can also be applied to applications (other than optical applications) in which it is not necessary for the cured product to have light transmittance. One example is an electronic device according to an embodiment. Specifically, the cured product is used for sealing electronic devices having large heat generation, for example, electronic devices including power elements such as rectifying elements and power transistors.

Additional features and advantages are described in, and will be apparent from, the following Detailed Description and the figures.

### BRIEF DESCRIPTION OF THE FIGURES

FIG. 1 is a section view schematically showing the configuration of a light-emitting device according to a first embodiment;

FIG. 2 is a section view schematically showing the configuration of a light-emitting device according to a second embodiment;

FIG. 3 is a section view schematically showing the configuration of a light-emitting device according to a third embodiment;

FIG. 4 is a section view schematically showing the configuration of a light-emitting device according to a fourth embodiment; and

FIG. 5 is a section view schematically showing the configuration of an existing light-emitting device.

### DETAILED DESCRIPTION

The present application will be described below in greater detail with referenced to the drawings according to an embodiment.

The mixing ratio by mass of a non-reactive siloxane-based compound to an addition-polymerization-curable silicone resin material is selected with a high degree of freedom in a curable resin material composition according to an embodiment. The mixing ratio should be 0.01 to 100, preferably 0.05 to 20, and more preferably 0.1 to 10. The mixing amount of the non-reactive siloxane-based compound can be properly selected in accordance with thermal shock resistance desired for the cured product of the curable resin material composition. However, the mixing ratio by mass of less than 0.01 is not preferable because the effect of mixing the non-reactive siloxane-based compound is not sufficiently provided. When the mixing ratio is more than 100, the cured product is extremely soft and can be too easily deformed by an external impact.

The non-reactive siloxane-based compound is preferably represented by the following general formula (1) or (2). Siloxane-based compounds represented by the general formula (1) or (2) have a high index of refraction of 1.49 to 1.58 due to the presence of a phenyl group or phenyl groups and hence mixing of these compounds does not decrease the index of refraction of the resultant curable resin material composition. As a result, the curable resin material composition and the cured product of this composition have an index of refraction of 1.50 or more. Therefore, use of such an optical material as a sealing member and/or a filling member of LED light-emitting devices increases the light-output efficiency of the LEDs.

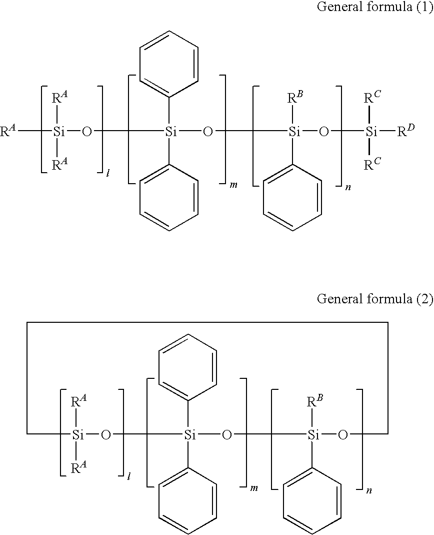

In the general formulae (1) and (2), R^{A}, R^{B}, and R^{D} each represent an alkyl group, an aralkyl group, a polyether group, a higher fatty acid ester group, a higher fatty acid amide group, or a fluoroalkyl group; R^{C} represents an alkyl group, an aralkyl group, a polyether group, a higher fatty acid ester group, a higher fatty acid amide group, a fluoroalkyl group, or a phenyl group; and 1, m, and n are each an integer of 0 or more and (m+n) is 1 or more.

An existing material is used as the addition-polymerization-curable silicone resin material in a curable resin material composition according to an embodiment. In curing of the composition, the SiH-group-containing siloxane-based compound and the C═C-bond-containing siloxane-based compound are polymerized by hydrosilylation addition reaction. To form a polymer by consecutive bonding of these monomer molecules, each monomer molecule of the SiH-group-containing siloxane-based compound contains two or more SiH groups and each monomer molecule of the C═C-bond-containing siloxane-based compound contains two or more carbon-carbon double bonds (C═C bonds).

Such monomers are not restricted except that the resultant silicone resin obtained by curing has a glass transition temperature of 50° C. or less. By using monomers having appropriate characteristics and appropriately adjusting the degree of polymerization, the viscosity of the addition-polymerization-curable silicone resin material before curing and the hardness of a cured product of the composition after curing can be made to be desired values or can be at least brought close to desired values. For example, when monomers having a low molecular weight are used, the viscosity of the addition-polymerization-curable silicone resin material can be decreased to a small value. When the degree of polymerization is increased or a monomer having increased number of carbon-carbon double bonds (C═C bonds) and/or SiH groups for addition reaction per molecule is used to form three-dimensional network polymer chains, the hardness and the strength of the resultant cured product can be enhanced.

Examples of the addition-polymerization-curable silicone resin material include X-32-2744-2/KER-2667B (trade name, manufactured by Shin-Etsu Chemical Co., Ltd.), KER-2667(A/B) (trade name, manufactured by Shin-Etsu Chemical Co., Ltd.), X-32-2430-3(A/B) (trade name, manufactured by Shin-Etsu Chemical Co., Ltd.), X-32-2723(A/B) (trade name, manufactured by Shin-Etsu Chemical Co., Ltd.), IVS5022(A/B) (trade name, manufactured by GE Toshiba Silicones Co., Ltd.), IVS5322(A/B) (trade name, manufactured by GE Toshiba Silicones Co., Ltd.), OE-6550(A/B) (trade name, manufactured by Dow Corning Toray Co., Ltd.), OE-6665(A/B) (trade name, manufactured by Dow Corning Toray Co., Ltd.), OE-6630(A/B) (trade name, manufactured by Dow Corning Toray Co., Ltd.), LS-6257(A/B) (trade name, manufactured by NuSil Technology LLC), LS-3357 (trade name, manufactured by NuSil Technology LLC), and OCK-451(A/B) (trade name, manufactured by Nye Lubricants, Inc.). A curable resin material composition according to an embodiment can contain one or more of the addition-polymerization-curable silicone resin materials described above.

The above-mentioned SiH-group-containing siloxane-based compound is preferably mainly composed of a moiety including an organic siloxane structure including a phenyl group or phenyl groups, for example, a moiety including methylphenylsiloxane or diphenylsiloxane, in particular, a moiety including the methylphenylsiloxane structure. Organic siloxanes have chemically stable structures. The presence of a phenyl group or phenyl groups in the SiH-group-containing siloxane-based compound is preferable because the index of refraction of the curable resin material composition is increased and, as a result, the index of refraction of a cured product of this composition is increased. The SiH-group-containing siloxane-based compound and/or the C═C-bond-containing siloxane-based compound preferably includes, as a substituent or substituents, an epoxy group, a carboxyl group, a methoxy group, an ethoxy group, a propoxy group, a glycidyl ether group, a polyether group, a carbinol group, or the like. These groups enhance adhesion of the silicone resin material to a substrate material or the like.

The curable resin material composition is preferably cured by thermally promoting polymerization caused by the above-described hydrosilylation addition reaction. Examples of the hydrosilylation addition reaction catalyst include catalysts containing platinum, palladium, or rhodium. Of these catalysts, catalysts containing platinum are preferably used because platinum-containing catalysts have high catalytic efficiency. Specific examples of such platinum-containing catalysts include platinum divinylsiloxane, platinum cyclovinylmethylsiloxane, tris(dibenzylideneacetone)diplatinum, platinic chloride, bis(ethylene)tetrachloro-diplatinum, cyclooctadienechloro-platinum, bis(cyclooctadiene)platinum, bis(dimethylphenylphosphine)dichloro-platinum, tetrakis(triphenylphosphine)platinum, and platinum-carbon.

The amount of the hydrosilylation addition reaction catalyst to be added is not particularly restricted as long as the catalyst is added in an amount to provide the intended catalytic effect. In general, the amount of the hydrosilylation addition reaction catalyst to be added is 0.1 to 500 ppm, preferably 3 to 100 ppm, in terms of the mass of platinum(palladium or rhodium) based on the C═C-bond-containing siloxane-based compound in the addition-polymerization-curable silicone resin material. When the amount of the hydrosilylation addition reaction catalyst to be added is excessive, problems such as yellow discoloration or brown discoloration in the cured product can occur. A curable resin material composition according to an embodiment can contain one or more of the addition reaction catalysts described above.

A curable resin material composition according to an embodiment is preferably transparent. A cured product of such a transparent composition can be used as an optical material. A plate of such a cured product having a thickness of 0.5 mm preferably has a light transmittance of 80% or more in terms of visible light having a wavelength of 380 to 750 nm. In this case, the cured product preferably has an index of refraction of 1.50 or more. Such a cured product is highly useful as an optical resin material that has a high index of refraction, is light in weight, inexpensive, durable, has good workability, and is suitable for mass production.

The non-reactive siloxane-based compound preferably has a viscosity of 1 Pa·s or less at 80° C. This viscosity is measured with an E-type viscometer. Hereinafter, viscosity below is also shown as a value measured with an E-type viscometer. Even when the addition-polymerization-curable silicone resin material has high viscosity, addition of such a non-reactive siloxane-based compound having low viscosity to this silicone resin material decreases the viscosity of the resultant curable resin material composition. In this case, by selecting the non-reactive siloxane-based compound that has appropriate viscosity, the viscosity of the curable resin material composition can be properly adjusted in accordance with applications and the resultant curable resin material composition has good handleability.

The curable resin material composition preferably has a viscosity of 100 Pa·s or less at 80° C. Such a curable resin material composition is suitably provided by a method such as thin-film coating, printing, or injection.

Any non-reactive siloxane-based compound that has high compatibility with the addition-polymerization-curable silicone resin material and has a pour point of 0° C. or less can be used as the non-reactive siloxane-based compound. Such a non-reactive siloxane-based compound can be properly selected from existing compounds. Examples of such compounds represented by the general formula (1) or (2) and have a viscosity of 1 Pa·s or less at 80° C. include HIVAC-F-4 (trade name, manufactured by Shin-Etsu Chemical Co., Ltd.), HIVAC-F-5 (trade name, manufactured by Shin-Etsu Chemical Co., Ltd.), KF-53 (trade name, manufactured by Shin-Etsu Chemical Co., Ltd.), KF-54 (trade name, manufactured by Shin-Etsu Chemical Co., Ltd.), KF-56 (trade name, manufactured by Shin-Etsu Chemical Co., Ltd.), SH702 (trade name, manufactured by Dow Coming Toray Co., Ltd.), PDM-1922 (trade name, manufactured by Gelest, Inc.), PMM-5021 (trade name, manufactured by Gelest, Inc.), PMM-0021 (trade name, manufactured by Gelest, Inc.), and PMM-0025 (trade name, manufactured by Gelest, Inc.). A curable resin material composition according to an embodiment can contain one or more of the non-reactive siloxane-based compounds described above.

A curable resin material composition according to an embodiment is suitably used as a filling material for light-emitting devices, the filling material being used for providing a refractive-index-adjusting member in a light path of a light-emitting device.

A curable resin material composition according to an embodiment preferably does not contain fine particles composed of inorganic materials having high indices of refraction, which can scatter light or cause turbidity. However, to adjust properties of such a curable resin material composition such as heat resistance, light resistance, adhesion, or reactivity, if necessary, the curable resin material composition may contain various additives. Such additives are added as long as the intended characteristics of a curable resin material composition are achieved.

For example, to enhance the heat resistance and the light resistance of the curable resin material composition, an existing hindered-amine-based compound such as TIN UVIN 123 (trade name, manufactured by Ciba Specialty Chemicals) or an existing hindered-phenol-based compound such as IRGANOX 1010 (trade name, manufactured by Ciba Specialty Chemicals) may be used. The amount of such a compound to be added is preferably 5 parts or less by weight based on 100 parts by weight of the curable resin material composition.

To enhance the adhesion of the curable resin material composition to various base materials, organic silicon compounds including functional groups such as an epoxy group, an alkoxy group, an acryloyloxy group, or a methacryloyloxy group can be used. The amount of such a compound to be added is preferably 15 parts or less by weight based on 100 parts by weight of the curable resin material composition.

Additionally, a polymerization inhibitor such as ethynyl cyclohexanol may be optionally added to the curable resin material composition. An additive for imparting thixotropic properties such as aerosol containing fine particles of silicon oxide may be optionally added to the curable resin material composition. To convert the wavelength of light emitted from an LED, a dye, a YAG fluorescent material, or the like may be optionally added to the curable resin material composition.

A method for preparing a curable resin material composition according to an embodiment is not particularly restricted. In general, such a curable resin material composition can be prepared by mixing components by stirring. The resultant curable resin material composition can be generally cured by heating at 100° C. to 200° C. for 10 minutes to 5 hours. Alternatively, the curable resin material composition may be cured by step curing in which the composition is subjected to a step of heating at about 100° C. for 1 to 2 hours and subsequently to a step of heating at 120° C. to 200° C. for 1 to 5 hours.

An optical material according to an embodiment is preferably used as a material for adjusting an index of refraction, a material for forming an optical lens, a material for forming an optical waveguide, or a material for reducing reflection. For example, the optical material can function as the material for adjusting an index of refraction when used as a filling member for light-emitting devices.

A light-emitting device according to an embodiment includes the light-emitting element and a sealing member for sealing the light-emitting element, wherein the optical material serves as the sealing member. The light-emitting element is disposed in a recess of a reflective cup. The sealing member is provided to be in contact with the light-emitting element and to fill the recess. Light emitted from the light-emitting element is output, through the optical material constituting the sealing member, directly or as a result of reflection at a wall of the reflective cup.

A light-emitting device according to another embodiment includes the light-emitting element, a sealing member for sealing the light-emitting element, and a filling member for filling a gap between the light-emitting element and the sealing member, wherein the optical material serves as the filling member.

This light-emitting device preferably has the following configuration. The light-emitting element is disposed in a recess of a reflective cup. The filling member is provided to be in contact with the light-emitting element and to fill the recess. The sealing member is provided to be in contact with the filling member. Light emitted from the light-emitting element is output, through the optical material constituting the filling member, directly or as a result of reflection at a wall of the reflective cup. This light-emitting device is used as a light source mainly outputting light toward the front.

Alternatively, the above-described light-emitting device may also have the following configuration. The sealing member is axially symmetric and includes a circular bottom surface, a convex-lens-shaped side surface, and a concave-lens-shaped top surface. A recess is formed in the bottom surface. The light-emitting element is disposed in the recess and at the center of the bottom surface. Light emitted from the light-emitting element is mainly output from the side surface directly or as a result of reflection at the top surface. This light-emitting device is used as a light source mainly outputting light toward the side.

A light-emitting device according to another embodiment includes the light-emitting element, a sealing member for sealing the light-emitting element, and a filling member for filling a gap between the light-emitting element and the sealing member, wherein the optical material serves as the filling member and the sealing member.

The above-mentioned light-emitting devices preferably include soil-resistant layers on the surfaces of the sealing members. Such a soil-resistant layer is preferably formed of a fluorine-based resin such as an alkoxysilane compound containing a perfluoropolyether group.

Hereinafter, light-emitting devices according to an embodiment are described in further detail. However, a light-emitting device according to the present application is not restricted to these embodiments.

### First Embodiment

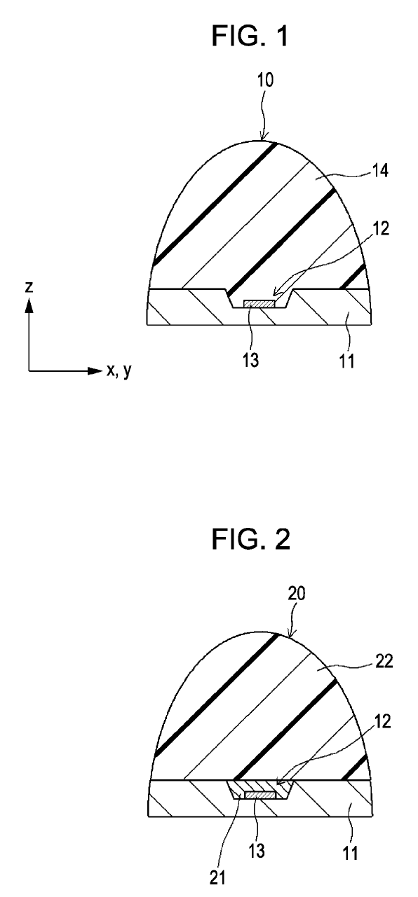

FIG. 1 is a section view schematically showing the configuration of a light-emitting device 10 according to a first embodiment. The light-emitting device 10 has a configuration similar to that of the existing general light-emitting device 100 shown in FIG. 5. Specifically, the light-emitting device 10 includes a reflective cup 11 having a recess 12, a light-emitting element 13 disposed in the recess 12, and a sealing member 14 provided to be in contact with the light-emitting element 13 and to fill the recess 12. Light emitted from the light-emitting element 13 is output through the sealing member 14 directly or as a result of reflection at a wall of the reflective cup 11. The sealing member 14 is provided on or above the light-emitting element 13 to have an appropriate shape and an appropriate thickness according to the purpose of the light-emitting device 10. For example, as shown in FIG. 1, the sealing member 14 is formed to have the shape of an artillery shell and to cover the recess 12 of the reflective cup 11.

The feature of the light-emitting device 10 is that the optical material constituting the sealing member 14 is an optical material according to an embodiment. Since this optical material has appropriate flexibility, distortion caused by stress can be reduced to a low level even under repeated damaging temperature cycles of high temperature while the light-emitting element 13 is turned on and low temperature while the light-emitting element 13 is turned off. As a result, for example, the optical material does not apply a stress causing disconnection to wires connecting an element electrode and a wiring electrode (not shown) in the light-emitting element 13 covered by the sealing member 14. This optical material also has good light resistance and heat resistance. In summary, use of an optical material according to an embodiment can provide the light-emitting device 10 with high reliability.

Examples of the light-emitting element 13 constituting the light-emitting device 10 include light-emitting diodes (LEDs) and semiconductor lasers. Examples of such light-emitting diodes include red light-emitting diodes emitting red light (for example, light having a wavelength of 640 nm), green light-emitting diodes emitting green light (for example, light having a wavelength of 530 nm), blue light-emitting diodes emitting blue light (for example, light having a wavelength of 450 nm), and white light-emitting diodes (for example, light-emitting diodes emitting white light as a result of the combination of ultraviolet-emitting diodes or blue light-emitting diodes and particles of a fluorescent material). Such light-emitting diodes may have “face up” configurations or flip chip configurations. Specifically, such a light-emitting diode is constituted by a substrate and a light-emitting layer formed on the substrate and may have a configuration where light is directly output from the light-emitting layer or a configuration where light emitted from the light-emitting layer is output through the substrate.

More specifically, a light-emitting diode (LED) includes, for example, a substrate; a first clad layer constituted by a compound semiconductor layer having a first conductivity type (for example, n-type) on the substrate; an active layer formed on the first clad layer; a second clad layer constituted by a compound semiconductor layer having a second conductivity type (for example, p-type) on the active layer; a first electrode electrically connected to the first clad layer; and a second electrode electrically connected to the second clad layer. These layers constituting the light-emitting diode may be formed with an existing compound semiconductor material in accordance with a desired wavelength of light to be emitted.

Alternatively, the light-emitting device may include a light-output lens described in a third embodiment below instead of the sealing member 14. As described below, a soil-resistant layer may be optionally formed on the surface of the sealing member 14.

### Second Embodiment

FIG. 2 is a section view schematically showing the configuration of a light-emitting device 20 according to a second embodiment. The light-emitting device 20 includes a reflective cup 11 having a recess 12, a light-emitting element 13 disposed in the recess 12, a filling member 21 provided to be in contact with the light-emitting element 13 and to fill the recess 12, and a sealing member 22 provided to be in contact with the filling member 21. Light emitted from the light-emitting element 13 is output through the filling member 21 and the sealing member 22 directly or as a result of reflection at a wall of the reflective cup 11.

The feature of the light-emitting device 20 is that the optical material constituting the filling member 21 is an optical material according to an embodiment. Since this optical material has appropriate flexibility, distortion caused by stress can be reduced to a low level even under repeated damaging temperature cycles of high temperature while the light-emitting element 13 is turned on and low temperature while the light-emitting element 13 is turned off. As a result, for example, the optical material does not apply a stress causing disconnection to wires connecting an element electrode and a wiring electrode (not shown) in the light-emitting element 13 covered by the filling member 21. This optical material also has good light resistance and heat resistance. In summary, use of an optical material according to an embodiment can provide the light-emitting device 20 with high reliability.

The sealing member 22 is provided on or above the light-emitting element 13 to have an appropriate shape and an appropriate thickness in accordance with the purpose of the light-emitting device 20. For example, as shown in FIG. 2, the sealing member 22 is provided to have the shape of an artillery shell, to seal the filling member 21, and to cover the recess 12 of the reflective cup 11. The sealing member 22 is formed of a transparent material (for example, a polycarbonate resin having an index of refraction of 1.6). In view of suppressing reflection of light at the interface between the sealing member 22 and the filling member 21, the sealing member 22 is preferably composed of a material having an index of refraction as high as that of an optical material constituting the filling member 21.

Examples of such a high refractive index material include plastic materials having a high refractive index such as Prestige (trade name, manufactured by SEIKO OPTICAL PRODUCTS CO., LTD., refractive index: 1.74), ULTIMAX V AS 1.74 (trade name, manufactured by SHOWA OPT. CO., LTD., refractive index: 1.74), and NL5-AS (trade name, manufactured by Nikon-Essilor Co., Ltd., refractive index: 1.74); optical glasses such as glass material NBFD11 (refractive index n: 1.78), M-NBFD82 (refractive index n: 1.81), and M-LAF81 (refractive index n: 1.731), all manufactured by HOYA CORPORATION; and inorganic dielectric materials such as KTiOPO₄ (refractive index n: 1.78) and lithium niobate [LiNbO₃] (refractive index n: 2.23).

Specific examples of a material for forming the sealing member 22 include epoxy-based resins, silicone-based resins, acrylic resins, polycarbonate resins, spiro compounds, polymethyl methacrylate, and copolymers of polymethyl methacrylate, diethyleneglycol-bis-allylcarbonate (CR-39), polymers and copolymers of a urethane-modified monomer of mono(meth)acrylate of (brominated) bisphenol A, polyester-based resins (for example, polyethylene terephthalate resins and polyethylene naphthalate resins), unsaturated polyesters, acrylonitrile-styrene copolymers, vinyl-chloride-based resins, polyurethane-based resins, and polyolefin-based resins. The sealing member 22 may be formed of at least one of the materials listed above. To enhance the heat resistance of the sealing member 22, aramid-based resins can be used. Use of such an aramid-based resin increases the upper limit of temperature to 200° C. or more in formation of a soil-resistant layer composed of a fluorine-based resin described below. As a result, the degree of freedom with which such a fluorine-based resin is selected can be enhanced.

Alternatively, the light-emitting device may include a light-output lens described in the third embodiment below instead of the sealing member 22. As described below, a soil-resistant layer may be optionally formed on the surface of the sealing member 22.

### Third Embodiment

In the light-emitting devices 10 and 20 described in the first and second embodiments, the path of light emitted from the light-emitting element 13 is changed by reflection at the reflective cup 11 or a convex lens effect provided by the sealing members 14 and 22. As a result, a large portion of light that is output from the light-emitting devices 10 and 20 is mainly directed in a direction perpendicular to the light-emitting surface (z-axis direction) while a small portion of the light is directed in a direction parallel to the light-emitting surface (x-axis direction and y-axis direction). Use of such a light-emitting device as a flat light source device such as a backlight source of a liquid crystal display can cause non-uniform intensity in the flat light source device because only a small portion of light is directed in a direction parallel to the light-emitting surface.

A light-emitting device according to a third embodiment is intended to avoid the above-described phenomenon. This light-emitting device is configured so that a large portion of light output from this device is mainly directed in a direction (x-axis direction and y-axis direction) parallel to the light-emitting surface. Such a light-emitting device is suitably used as a flat light source device such as a backlight source of a liquid crystal display.

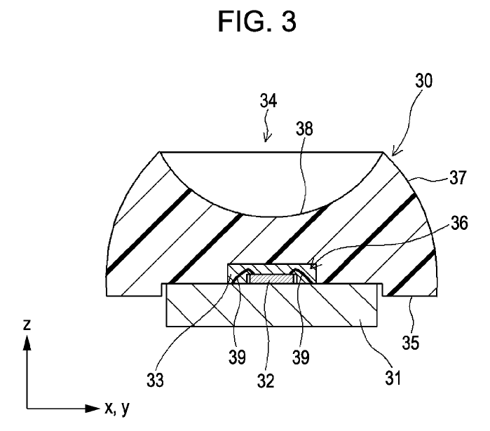

FIG. 3 is a section view schematically showing the configuration of a light-emitting device 30 according to the third embodiment. The light-emitting device 30 includes a substrate 31, a light-emitting element (light-emitting diode) 32 disposed on the substrate 31, and wires 39 for connecting a wiring portion (not shown) formed on the substrate 31 and the light-emitting element 32. The light-emitting device 30 further includes a light-output lens 34 on the light-output side of the light-emitting element 32. A recess 36 is formed in a bottom surface 35 of the light-emitting device 30. The light-emitting element 32 is contained in the recess 36 and the gap between the light-emitting element 32 and the light-output lens 34 is filled with a filling member 33.

The light-output lens 34 is axially symmetric and includes the circular bottom surface 35, a side surface 37, and a top surface 38. A flat light source (the light-emitting element 32) having a finite size is disposed in the center portion of the bottom surface 35. The light-output lens 34 is described in further detail in Japanese Unexamined Patent Application Publication No. 2007-102139. Examples of a material for forming the light-output lens 34 include the materials for forming the sealing member 22 described in the second embodiment.

Light emitted upward (z-axis direction) from the light-emitting element 32 passes through the filling member 33 and the light-output lens 34 and reaches the top surface 38 of the light-output lens 34, the top surface 38 being the boundary surface of the light-output lens 34 and the ambient environment. A portion of light incident upon the top surface 38 at a small incident angle is refracted at the top surface 38 and the path of this light is changed by a convex lens effect to broaden the flux of the light; however, the light is still output upward. In contrast, a large portion of light incident upon the top surface 38 at a large incident angle is totally reflected by the top surface 38 and the path of this light is changed to be mainly directed in a direction parallel to the light-emitting surface (x-axis direction and y-axis direction), and output from the side surface 37. Light emitted from the light-emitting element 32 to the side surface 37 of the light-output lens 34 passes through the filling member 33 and the light-output lens 34 and is subsequently made incident on the side surface 37 at a small incident angle. As a result, this light is only slightly refracted, however, travels substantially in a straight line and is output via the side surface 37. In summary, a large portion of light emitted from the light-emitting element 32 is output via the side surface 37 directly or as a result of reflection at the top surface 38 of the lens 34.

The feature of the light-emitting device 30 according to the third embodiment is that the optical material constituting the filling member 33 is an optical material according to an embodiment. Since this optical material has appropriate flexibility, distortion caused by stress can be reduced to a low level even under repeated damaging temperature cycles of high temperature while the light-emitting element 32 is turned on and low temperature while the light-emitting element 32 is turned off. As a result, for example, the optical material does not apply a stress causing disconnection to the wires 39 contained in the filling member 33. This optical material also has good light resistance and heat resistance. In summary, use of an optical material according to an embodiment can provide the light-emitting device 30 with high reliability.

The light-output lens 34 is additionally described below in terms of its important points. Cylindrical coordinates (r, φ, z) are considered where the center of the bottom surface 35 is defined as a point of origin and a line that is normal to the bottom surface 35 and passes through the center of the bottom surface 35 is defined as the z-axis. In this case,

the top surface 38 is aspherical and rotationally symmetric with respect to the z-axis, the top surface 38 totally reflecting, among emitted light having the half solid angle from the flat light source, a portion of an emitted light component having a polar angle smaller than the polar angle θ₀ at a point of intersection of the side surface 37 and the top surface 38;

the side surface 37 is aspherical and rotationally symmetric with respect to the z-axis, the side surface 37 passing therethrough, among emitted light having the half solid angle from the flat light source, an emitted light component having a polar angle larger than the polar angle θ₀ and an emitted light component totally reflected by the top surface 38; and

as for a function r=fₛ(z), where z is a variable representing the aspherical side surface 37 and a z coordinate at a point of intersection of the side surface 37 and the top surface 38 is defined as z₁, the function monotonically increases in a closed interval of 0≦z≦z₁ where z decreases; and the function has at least one maximum point of the absolute value of the second order differential coefficient |d²r/dz²| of z in the closed interval.

Such a light-output lens is not restricted to the light-output lens 34 shown in FIG. 3 and light-output lenses having various configurations and structures can be used.

### Fourth Embodiment

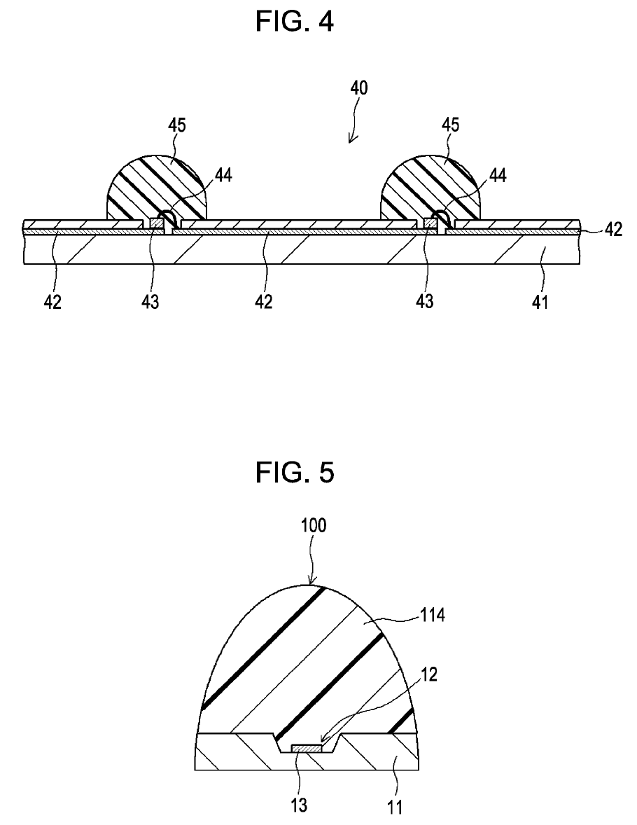

FIG. 4 is a section view schematically showing the configuration of a light-emitting device 40 according to a fourth embodiment. The light-emitting device 40 includes a wiring substrate 41, one or more light-emitting elements 43 disposed on the wiring substrate 41, and sealing members 45 formed on the wiring substrate 41 for sealing the light-emitting elements 43. The light-emitting elements 43 are light-emitting diode (LED) chips or the like. The element electrodes (not shown) of the light-emitting elements 43 are connected to wiring electrodes of a wiring layer 42 directly or via wires 44 or solder bumps.

As in the first embodiment, the feature of the light-emitting device 40 is that the optical material constituting the sealing member 45 is an optical material according to an embodiment. Since this optical material has appropriate flexibility, distortion caused by stress can be reduced to a low level even under repeated damaging temperature cycles of high temperature while the light-emitting elements 43 are turned on and low temperature while the light-emitting elements 43 are turned off. As a result, for example, the optical material does not apply a stress causing disconnection to the wires 44 connecting the element electrodes of the light-emitting elements 43 and the wiring electrodes, the wires 44 being contained in the sealing members 45. This optical material also has good light resistance and heat resistance. In summary, use of an optical material according to an embodiment can provide the light-emitting device 40 with high reliability.

By disposing a set of a red LED, a green LED, and a blue LED that correspond to three primary colors on the single wiring substrate 41, white light can be produced as a result of mixing of beams emitted from these LEDs. The light-emitting device 40 including such LED sets arranged in an array or in a matrix can be used as a linear or flat light source outputting white light. Furthermore, a combination of such linear or flat light sources 40 arranged in an array or in a matrix can be used as a backlight device for transmission color liquid crystal display panels.

The light-emitting devices 10 to 40 described in the first to fourth embodiments can be used in any field where emitted light is used. Examples of applications of such light-emitting devices include backlights of liquid crystal display apparatuses, the backlights including flat light source units and currently divided into two types: direct-lighting type and edge-lighting type (side-lighting type); lighting fittings and lamps for transportation means such as automobiles, trains, ships, and planes (e.g. headlights, taillights, high mounted stop lights, small lights, turn signal lamps, fog lights, interior lamps, lamps for instrument panels, light sources contained in various buttons, destination sign lamps, emergency lights, and emergency exit lights); various lighting fittings and lamps for buildings (e.g. exterior lamps, interior lamps, light fixtures, emergency lights, and emergency exit lights); street lights; various indicator lighting fittings for traffic lights, signboards, apparatuses and devices; and lighting fittings and lighting units in dark places such as tunnels and underground passages.

Optionally, a soil-resistant layer may be formed on the surface of the sealing member 14 or 22 or the light-output lens 34. The thickness of such a soil-resistant layer is not particularly restricted. However, in view of providing sufficient transparency, the thickness of a soil-resistant layer is preferably 0.5 to 50 nm, more preferably 1 to 20 nm. Examples of a material for forming a soil-resistant layer include fluorine-based resins, that is, basically resins including perfluoropolyether groups, preferably, resins further including alkoxysilyl groups.

Such materials for forming a soil-resistant layer are basically not restricted except that the materials have the molecular structure of perfluoropolyether groups. In practice, there are restrictions based on ease of synthesis, that is, feasibility. Specifically, an alkoxysilane compound including a perfluoropolyether group represented by the following general formula (3) is an example of a preferred fluorine-based resin for forming a soil-resistant layer.

R_{f}(CO—U—R⁴—Si(OR⁵)₃)ⱼ (3)

In this formula, R_{f} represents a perfluoropolyether group, U represents a divalent atom or group, R⁴ represents an alkylene group, R⁵ represents an alkyl group, and j=1 or 2.

The molecular weight of such an alkoxysilane compound represented by the general formula (3) is not particularly restricted. However, the number-average molecular weight of this compound is 4×10² to 1×10⁴, preferably 5×10² to 4×10³, in view of stability, easy handling, and the like.

The perfluoropolyether group R_{f} is a monovalent or divalent perfluoropolyether group. Specific structures of such a perfluoropolyether group are shown as general formulae (4) to (7) below. However, the structure of the perfluoropolyether group R_{f} is not restricted to these structures. In the general formulae (4) to (7), p and q are preferably integers of 1 to 50; k to n represents integers of 1 or more; and 1/m is preferably in the range of 0.5 to 2.0.

In the case of j=2, the following general formula (4) is one example of the perfluoropolyether group R_{f} in the general formula (3).

—CF₂—(OC₂F₄)ₚ—(OCF₂)_{q}—OCF₂— (4)

In the case of j=1, the following general formulae (5) to (7) are examples of the perfluoropolyether group R_{f} in the general formula (3). In these formulae, all the hydrogen atoms in the alkyl groups are not necessarily replaced by fluorine atoms, and the alkyl groups may partially contain hydrogen atoms.

F(CF₂CF₂CF₂)ₖ— (5)

CF₃(OCF(CF₃)CF₂)ₗ(OCF₂)ₘ— (6)

F(CF(CF₃)CF₂)ₙ— (7)

Additionally, the following materials including a perfluoropolyether group may also be used for forming a soil-resistant layer: perfluoropolyethers including polar end groups (see Japanese Unexamined Patent Application Publication No. 09-127307); compositions for forming soil-resistant films, the compositions containing alkoxysilane compounds including perfluoropolyether groups having specific structures (see Japanese Unexamined Patent Application Publication No. 09-255919); and surface modification materials obtained by combining alkoxysilane compounds including perfluoropolyether groups and various materials (see Japanese Unexamined Patent Application Publication Nos. 09-326240, 10-26701, 10-120442, and 10-148701).

U represents a divalent atom or atomic group for connecting the perfluoropolyether group R_{f} and R⁴ and is not particularly restricted. However, U is preferably an atom or an atomic group other than carbon such as —O—, —NH—, or —S— in view of ease of synthesis. R⁴ represents a hydrocarbon group and preferably includes 2 to 10 carbon atoms. Specific examples of R⁴ include alkylene groups such as a methylene group, an ethylene group, and a propane-1,3-diyl group; and a phenylene group. R⁵ represents an alkyl group constituting an alkoxy group and generally includes three or less carbon atoms. Thus, examples of R⁵ include an isopropyl group, a propyl group, an ethyl group, and a methyl group. Alternatively, R⁵ may include 4 or more carbon atoms.

In formation of a soil-resistant layer, a fluorine-based resin (for example, an alkoxysilane compound represented by the general formula (3)) is generally used after being diluted with a solvent. Such a solvent is not particularly restricted; however, the solvent should be selected in consideration of the stability of a composition, wettability of a surface of a sealing member, volatility and the like. Specific examples of such a solvent include alcohol-based solvents such as ethyl alcohol, ketone-based solvents such as acetone, and hydrocarbon-based solvents such as hexane. These solvents may be used alone or in combination (mixture of two or more solvents).

A solvent for dissolving a fluorine-based resin should be selected in consideration of the stability of a composition to be used, wettability of a surface of a sealing member, volatility and the like. For example, fluorinated-hydrocarbon-based solvents may also be used. Fluorinated-hydrocarbon-based solvents are compounds in which hydrogen atoms in hydrocarbon-based solvents such as aliphatic hydrocarbons, cyclic hydrocarbons, or ethers are partially or completely replaced by fluorine atoms. Examples of such fluorinated-hydrocarbon-based solvents include ZEORORA-HXE (trade name, boiling point: 78° C.), perfluoroheptane (boiling point: 80° C.), and perfluorooctane (boiling point: 102° C.), all being manufactured by ZEON CORPORATION; hydrofluoropolyethers such as H-GALDEN-ZV75 (boiling point: 75° C.), H-GALDEN-ZV85 (boiling point: 85° C.), H-GALDEN-ZV100 (boiling point: 95° C.), H-GALDEN-C (boiling point: 130° C.), and H-GALDEN-D (boiling point: 178° C.), and perfluoropolyethers such as SV-110 (boiling point: 110° C.) and SV-135 (boiling point: 135° C.), these listed being trade names and manufactured by Ausimont Corporation; and perfluoroalkanes such as FC series manufactured by Sumitomo 3M Limited. Among these fluorinated-hydrocarbon-based solvents, for the purpose of forming a soil-resistant layer not having unevenness and having uniform thickness, a solvent or solvents for dissolving the above-described fluorine-based compounds are preferably selected from those having a boiling point of 70° C. to 240° C. In particular, one or more selected from hydrofluoropolyethers (HFPE) and hydrofluorocarbons (HFC) is used alone or in combination (mixture of two or more solvents). When such a solvent has a too low boiling point, for example, unevenness of coating tends to occur. In contrast, when such a solvent has a too high boiling point, drying of the resultant soil-resistant layer takes time and formation of a soil-resistant layer with uniform thickness tends to be difficult.

The above-described fluorine-based compounds have high solubility in HFPE and HFC and hence use of HFPE and/or HFC provides good coated surfaces.

A soil-resistant layer can be formed by coating a solution obtained by diluting the above-described fluorine-based resin with a solvent to the surface of a sealing member, and, for example, heating the coated solution to volatilize the solvent and to bond the material constituting the sealing member and the fluorine-based resin constituting the soil-resistant layer. Herein, various methods for general coating operations can be used and methods such as spin coating and spray coating can be preferably used. Alternatively, a method of impregnating a material such as paper or cloth with a solution and coating the solution with the impregnated material may be used in view of workability. The heating temperature should be selected in consideration of properties of the sealing member such as heat resistance. For example, when a polyethylene terephthalate resin is used to form the sealing member, the heating temperature is preferably in the range of 30° C. to 80° C.

Alkoxysilane compounds represented by the general formula (3) include perfluoropolyether groups in the molecules and, as a result, have water repellency and enhanced resistance to soil. Therefore, formation of a soil-resistant layer containing such an alkoxysilane compound imparts characteristics such as resistance to wear and resistance to soil to the surface of the sealing member.

A material for forming a soil-resistant layer preferably further contains at least one material selected from the group consisting of acids, bases, phosphates, and acetylacetone as a catalyst for promoting reaction between the material constituting the sealing member and the material constituting the soil-resistant layer. Specific examples of such a catalyst include acids such as hydrochloric acid, bases such as ammonia, and phosphates such as dilauryl phosphate. The amount of such a catalyst to be added is, for example, 1×10⁻³ to 1 mmol/L. When an acid or a base is added, addition of a carbonyl compound such as acetylacetone enhances the reactivity of the acid or the base. For this reason, addition of a carbonyl compound to a composition for forming a soil-resistant layer is recommended. The amount of such a carbonyl compound to be added is about 1×10⁻¹ to 1×10² mmol/L. In this way, by adding such a catalyst, strong bonding can be achieved between a sealing member and a soil-resistant layer even when the heating (drying) temperature is decreased. This is advantageous in conducting the production process and the range from which a material for forming the sealing member is selected is widened.

Hereinafter, examples are described where a soil-resistant layer was formed on the surface of the sealing member 22 of the light-emitting device 20, which is described in the second embodiment.

Two parts by weight of an alkoxysilane compound (average molecular weight: about 4000) having perfluoropolyether groups at the both ends and represented by the following general formula (8) were dissolved as a fluorine-based resin in 200 parts by weight of a hydrofluoropolyether (trade name: H-GALDEN, manufactured by Solvay Solexis S.p.A., boiling point: 130° C.) as a fluorine-based solvent.

R_{f}(CO—NH—C₃H₆—Si(OCH₂CH₃)₃)₂ (8)

After that, 0.08 parts by weight of perfluoropolyether phosphate was added as a catalyst to the resultant solution and this solution was made to be uniform. The resultant solution was filtered through a membrane filter to provide a composition for forming a soil-resistant layer. This composition was coated onto the surface of the sealing member 22 by spraying. The coated composition was dried at 70° C. for an hour. Thus, the light-emitting device 20 including a soil-resistant layer on the surface of the sealing member 22 was obtained.

Corn starch was sprinkled over the sealing member 22 of the thus-obtained light-emitting device 20. The corn starch was then removed from the sealing member 22 with an air blow gun. Observation of the surface of the sealing member 22 with an optical microscope revealed complete removal of the corn starch.

Another light-emitting device 20 was produced in the same manner as described above except that a resin (average molecular weight: about 2000) represented by the following general formula (9) was used as a fluorine-based resin.

R_{f}═—CH₂CF₂(OC₂F₄)ₚ(OCF₂)_{q}OCF₂— (9)

Corn starch was sprinkled over the sealing member 22 of the thus-obtained light-emitting device 20. The corn starch was then removed from the sealing member 22 with an air blow gun. Observation of the surface of the sealing member 22 with an optical microscope revealed complete removal of the corn starch.

Another light-emitting device 20 was produced in the same manner as described above except that a resin (average molecular weight: about 650) represented by the following general formula (10) was used as a fluorine-based resin.

CF₃(CF₂)₈CH₂Si(OC₂H₅)₃ (10)

Corn starch was sprinkled over the sealing member 22 of the thus-obtained light-emitting device 20. The corn starch was then removed from the sealing member 22 with an air blow gun. Observation of the surface of the sealing member 22 with an optical microscope revealed complete removal of the corn starch.

Hereinafter, examples according to an embodiment of the present application are described. However, the present application is not restricted to these examples below.

As for Examples 1 to 3, examples are described where the curable resin material composition was prepared; the cured product of this composition and the light-emitting device were produced; the curable resin material composition was measured for an index of refraction; the cured product was measured for glass transition temperature and light transmittance; and a light resistance test, a heat resistance test, and a thermal shock resistance test were conducted.

### EXAMPLE 1

<Preparation and Evaluation of Curable Resin Material Composition>

In Example 1, X-32-2430-3(A/B) (trade name, manufactured by Shin-Etsu Chemical Co., Ltd.) was used as the addition-polymerization-curable silicone resin material; and Siloxane 1 represented by the following structural formula (1) was used as the non-reactive siloxane-based compound. X-32-2430-3(A/B) and Siloxane 1 were mixed in a ratio of 80:20 by mass and stirred to prepare a curable resin material composition. When X-32-2430-3(A/B) alone is cured, the resultant cured product has a glass transition temperature of −40° C. Siloxane 1 has a pour point of −35° C., a viscosity of 40 mPa·s (at 25° C.), and an index of refraction of 1.556.

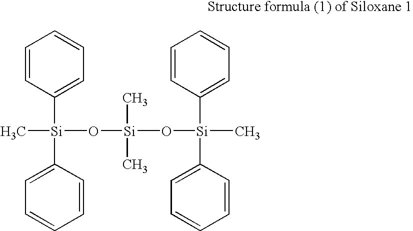

This curable resin material composition was measured for the index of refraction with an existing Abbe refractometer (a model NAR-4T manufactured by ATAGO CO., LTD.). In this measurement, sodium D line (wavelength: 589 nm) was used and the measurement temperature was 25° C.

<Preparation and Evaluation of Cured Product of Curable Resin Material Composition>

The curable resin material composition was sandwiched between two mold releasing films composed of silicone rubber sheets. The thickness of the sandwiched composition was adjusted and then the resultant structure was heated in an oven at 150° C. for an hour to cure the composition. After the structure was allowed to cool to room temperature, the mold releasing films were removed and a plate of a cured product with a thickness of 0.5 mm was obtained.

This cured product plate (sample) was measured for the light transmittance of the cured product with an UV-visible spectrophotometer (a model U-3410 manufactured by Hitachi High-Technologies Corporation) in the measurement wavelength range of 380 to 750 nm. The cured product plate (sample) was also measured for the glass transition temperature of the cured product with a physical-pendulum-type physical properties testing instrument (a model RPT-3000W manufactured by A&D Company, Limited). The cured product plate (sample) was subjected to a light resistance test in accordance with JIS A1415 with a Fade-Ometer for 96 hours and the sample was inspected for discoloration. The cured product plate (sample) was also subjected to a heat resistance test in the atmosphere at 150° C. for 96 hours and the sample was inspected for change in the transparency before and after the test.

<Production of Light-Emitting Device and Thermal Shock Resistance Test for Cured Product>

An LED chip base (a base, a bare chip, and wires on the base) was obtained by removing a lens portion and a sealing resin from a commercially available LED (LUXEON (trademark) III manufactured by Philips Lumileds Lighting Company). The curable resin material composition described above was provided to entirely cover the bare chip and the wires of the LED chip base. The resultant structure was heated in an oven at 150° C. for an hour to cure the curable resin material composition and subsequently allowed to cool to room temperature. Thus, an LED device sealed with the cured product of the curable resin material composition was obtained.

This LED device (sample) was subjected to a thermal shock resistance test where a cycle of holding the sample at −40° C. for 20 minutes and subsequently holding the sample at 120° C. for 20 minutes were repeated 700 times. The sample was inspected for the presence of separation of the cured product of the curable resin material composition, damage in the chip, and disconnection of the wires (n=10).

### EXAMPLE 2

In Example 2, Siloxane 2 represented by the following structural formula (2) was used as the non-reactive siloxane-based compound instead of Siloxane 1. Other than that, as in Example 1, preparation and evaluation of a curable resin material composition and a cured product of this composition and production and evaluation of a light-emitting device were conducted. Siloxane 2 has a pour point of −15° C., a viscosity of 190 mPa·s (at 25° C.), and an index of refraction of 1.588.

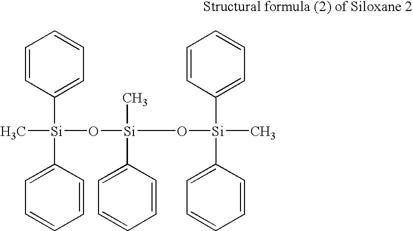

### EXAMPLE 3

In Example 3, OE-6550(A/B) (trade name, manufactured by Dow Corning Toray Co., Ltd.) was used as the addition-polymerization-curable silicone resin material. Other than that, as in Example 1, preparation and evaluation of a curable resin material composition and a cured product of this composition and production and evaluation of a light-emitting device were conducted. When OE-6550(A/B) alone is cured, the resultant cured product has a glass transition temperature of −20° C.

### COMPARATIVE EXAMPLE 1

In Comparative Example 1, a light-emitting device was produced as in Example 1 except that the non-reactive siloxane-based compound was not added to the addition-polymerization-curable silicone resin material. This light-emitting device was subjected to a thermal shock resistance test and disconnection of the wires was observed.

### COMPARATIVE EXAMPLE 2

In Comparative Example 2, a light-emitting device was produced as in Example 1 except that a non-reactive siloxane-based compound 102 having a pour point of 20° C. was used as the non-reactive siloxane-based compound. This light-emitting device was subjected to a thermal shock resistance test and disconnection of the wires was observed.

### COMPARATIVE EXAMPLE 3

In Comparative Example 3, a light-emitting device was produced as in Example 1 except that an addition-polymerization-curable silicone resin material 103 having a glass transition temperature of 75° C. was used as the addition-polymerization-curable silicone resin material. This light-emitting device was subjected to a thermal shock resistance test and disconnection of the wires was observed.

Table 1 below shows the components used for preparing the compositions of Examples 1 to 3 and Comparative Examples 2 and 3 (addition-polymerization-curable silicone resin materials, the glass transition temperatures of cured products of these materials, non-reactive siloxanes, and the pour points of these siloxanes), the indices of refraction of the compositions, and the glass transition temperatures of cured products of the compositions.

TABLE 1

| | Components of curable resin | | | | | |
|---|---|---|---|---|---|---|
| | material composition (mass %) | | | | Composition | |
| | | Glass transition | | | | Glass transition |
| | Silicone resin | temperature of | Non-reactive | (Pour | Index of | temperature of |
| | material (80%) | cured product | siloxane (20%) | point) | refraction | cured product |
| Example 1 | X-32-2430-3(A/B) | (−40° C.) | Siloxane 1 | (−35° C.) | 1.52 | −40° C. or less |
| Example 2 | X-32-2430-3(A/B) | (−40° C.) | Siloxane 2 | (−15° C.) | 1.52 | −40° C. or less |
| Example 3 | OE-6550(A/B) | (−20° C.) | Siloxane 1 | (−35° C.) | 1.55 | −40° C. |
| Comparative | X-32-2430-3(A/B) | (−40° C.) | Siloxane 102 | (20° C.) | Not | −40° C. or less |
| Example 2 | | | | | measured | |
| Comparative | Resin material 103 | (75° C.) | Siloxane 1 | (−35° C.) | Not | 40° C. |
| Example 3 | | | | | measured | |

The cured products obtained in Examples 1 to 3 all had a light transmittance of 90% or more and no change in the color and in the transparency was respectively detected in the light resistance tests and the heat resistance tests. As shown in Table 1, the following fact has been established with Examples 1 to 3 in which the curable resin material compositions according to embodiments were used. A cured product having an index of refraction of 1.50 or more and a glass transition temperature of 40° C. or less can be obtained by curing a curable resin material composition that is prepared by mixing an existing addition-polymerization-curable silicone resin material whose cured product has a glass transition temperature of 80° C. or less and a non-reactive siloxane-based compound having a pour point of 0° C. or less. The LED light-emitting devices including such cured products as sealing members were subjected to the thermal shock resistance tests and no failure such as separation of the sealing members, damage in the chips, or disconnection of the wires was observed. That is, the cured products had a flexibility sufficient not to cause failure such as separation of the sealing members, damage in the chips, or disconnection of the wires.

In contrast, the LED light-emitting devices including the cured products obtained in Comparative Examples 1 to 3 as sealing members were subjected to the thermal shock resistance tests and disconnection of the wires was observed. That is, these cured products did not have a flexibility sufficient not to cause failure such as separation of the sealing members, damage in the chips, or disconnection of the wires. Such an insufficient flexibility was caused for Comparative Example 1 because a non-reactive siloxane-based compound was not added. For Comparative Example 2, the curable resin material composition was prepared with the non-reactive siloxane-based compound having a pour point of more than 0C. For Comparative Example 3, the curable resin material composition was prepared with the addition-polymerization-curable silicone resin material in which the cured product of this material alone has a glass transition temperature of more than 50° C.

It should be understood that various changes and modifications to the presently preferred embodiments described herein will be apparent to those skilled in the art. Such changes and modifications can be made without departing from the spirit and scope and without diminishing its intended advantages. It is therefore intended that such changes and modifications be covered by the appended claims.

The application is claimed as follows:

1. A curable resin material composition comprising:
an addition-polymerization-curable silicone resin material that gives a silicone resin having a glass transition temperature of 50° C. or less when cured, the addition-polymerization-curable silicone resin material including,
a SiH-group-containing siloxane-based compound containing a SiH group where a silicon atom is bonded to a hydrogen atom,
a C═C-bond-containing siloxane-based compound containing a carbon-carbon double bond capable of effecting addition reaction with the SiH group, and
a hydrosilylation addition reaction catalyst; and
a non-reactive siloxane-based compound that does not react with the SiH-group-containing siloxane-based compound or the C═C-bond-containing siloxane-based compound, that is compatible with the addition-polymerization-curable silicone resin material, and that has a pour point of 0° C. or less.

2. The curable resin material composition according to claim 1, wherein a mixing ratio by mass of the non-reactive siloxane-based compound to the addition-polymerization-curable silicone resin material is 0.01 to 100.

3. The curable resin material composition according to claim 2, wherein the mixing ratio by mass is 0.1 to 100.

4. The curable resin material composition according to claim 1, wherein the non-reactive siloxane-based compound is represented by general formula (1) or (2) below, 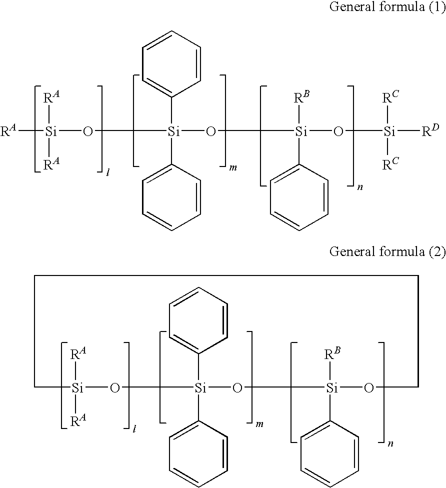
wherein R^{A}, R^{B}, and R^{D} each represent an alkyl group, an aralkyl group, a polyether group, a higher fatty acid ester group, a higher fatty acid amide group, or a fluoroalkyl group; R^{C} represents an alkyl group, an aralkyl group, a polyether group, a higher fatty acid ester group, a higher fatty acid amide group, a fluoroalkyl group, or a phenyl group; and 1, m, and n are each an integer of 0 or more and (m+n) is 1 or more.

5. The curable resin material composition according to claim 1, wherein the SiH-group-containing siloxane-based compound is mainly composed of a moiety including an organic siloxane structure containing a phenyl group.

6. The curable resin material composition according to claim 1, having an index of refraction of 1.50 or more.

7. The curable resin material composition according to claim 1, wherein the non-reactive siloxane-based compound has a viscosity of 1 Pa·s or less at 80° C.

8. The curable resin material composition according to claim 1, having a viscosity of 100 Pa·s or less at 80° C.

9. The curable resin material composition according to claim 1, being used as a filling material for providing a refractive-index-adjusting member in a light path of a light-emitting device.

10. An optical material comprising a cured product obtained by curing a curable resin material composition, the curable resin material composition including an addition-polymerization-curable silicone resin material that gives a silicone resin having a glass transition temperature of 50° C. or less when cured, the addition-polymerization-curable silicone resin material including,
a SiH-group-containing siloxane-based compound containing a SiH group where a silicon atom is bonded to a hydrogen atom,
a C═C-bond-containing siloxane-based compound containing a carbon-carbon double bond capable of effecting addition reaction with the SiH group, and
a hydrosilylation addition reaction catalyst; and
a non-reactive siloxane-based compound that does not react with the SiH-group-containing siloxane-based compound or the C═C-bond-containing siloxane-based compound, that is compatible with the addition-polymerization-curable silicone resin material, and that has a pour point of 0° C. or less.

11. The optical material according to claim 10, wherein the optical material is used as a material for adjusting an index of refraction, a material for forming an optical lens, a material for forming an optical waveguide, or a material for reducing reflection.

12. The optical material according to claim 10, wherein the optical material is used as a filling member for a light-emitting device.

13. A light-emitting device comprising:
a light-emitting element; and
an optical material comprising a cured product obtained by curing a curable resin material composition, the curable resin material composition including
an addition-polymerization-curable silicone resin material that gives a silicone resin having a glass transition temperature of 50° C. or less when cured, the addition-polymerization-curable silicone resin material including,
a SiH-group-containing siloxane-based compound containing a SiH group where a silicon atom is bonded to a hydrogen atom,
a C═C-bond-containing siloxane-based compound containing a carbon-carbon double bond capable of effecting addition reaction with the SiH group, and
a hydrosilylation addition reaction catalyst; and
a non-reactive siloxane-based compound that does not react with the SiH-group-containing siloxane-based compound or the C═C-bond-containing siloxane-based compound, that is compatible with the addition-polymerization-curable silicone resin material, and that has a pour point of 0° C. or less;
wherein the light-emitting device is configured to output, through the optical material, light emitted from the light-emitting element.

14. The light-emitting device according to claim 13, wherein the optical material serves as a sealing member for sealing the light-emitting element.

15. The light-emitting device according to claim 14, further comprising:
a reflective cup,
wherein the light-emitting element is disposed in a recess of the reflective cup, the sealing member is provided to be in contact with the light-emitting element and to fill the recess, and light emitted from the light-emitting element is output, through the optical material constituting the sealing member, directly or as a result of reflection at a wall of the reflective cup.

16. The light-emitting device according to claim 13, further comprising:
a sealing member for sealing the light-emitting element,
wherein the optical material serves as a filling member for filling a gap between the light-emitting element and the sealing member.

17. The light-emitting device according to claim 16, further comprising:
a reflective cup,
wherein the light-emitting element is disposed in a recess of the reflective cup, the filling member is provided to be in contact with the light-emitting element and to fill the recess, the sealing member is provided to be in contact with the filling member, and light emitted from the light-emitting element is output, through the optical material constituting the filling member, directly or as a result of reflection at a wall of the reflective cup.

18. The light-emitting device according to claim 16, wherein the sealing member is axially symmetric and includes a circular bottom surface, a convex-lens-shaped side surface, and a concave-lens-shaped top surface; a recess is formed in the bottom surface; the light-emitting element is disposed in the recess and at the center of the bottom surface; and light emitted from the light-emitting element is mainly output from the side surface directly or as a result of reflection at the top surface.

19. The light-emitting device according to claim 13, wherein the optical material serves as a sealing member for sealing the light-emitting element and a filling member for filling a gap between the light-emitting element and the sealing member.

20. The light-emitting device according to any one of claims 14, 16, and 19, wherein a soil-resistant layer is provided on a surface of the sealing member.

21. The light-emitting device according to claim 20, wherein the soil-resistant layer is composed of a fluorine-based resin.

22. The light-emitting device according to claim 13, wherein the light-emitting element includes at least one light-emitting element disposed on a wiring substrate, and the optical material serves as a sealing member for sealing the light-emitting element, the sealing member being provided on the wiring substrate.

23. The light-emitting device according to claim 22, wherein the at least one light-emitting element includes a plurality of light-emitting diodes arranged in an array or in a matrix to constitute a backlight unit.

24. A method for producing a light-emitting device comprising:
mounting a light-emitting element on a substrate;
providing a curable resin material composition on the substrate to cover the light-emitting element wherein the curable resin material including an addition-polymerization-curable silicone resin material that gives a silicone resin having a glass transition temperature of 50° C. or less when cured, the addition-polymerization-curable silicone resin material including,
a SiH-group-containing siloxane-based compound containing a SiH group where a silicon atom is bonded to a hydrogen atom,
a C═C-bond-containing siloxane-based compound containing a carbon-carbon double bond capable of effecting addition reaction with the SiH group, and
a hydrosilylation addition reaction catalyst; and
a non-reactive siloxane-based compound that does not react with the SiH-group-containing siloxane-based compound or the C═C-bond-containing siloxane-based compound, that is compatible with the addition-polymerization-curable silicone resin material, and that has a pour point of 0° C. or less; and
curing the curable resin material composition to provide a cured product and to seal the light-emitting element with the cured product.

25. An electronic device comprising:
an electronic element, and
a cured product obtained by curing a curable resin material composition wherein the curable resin material including an addition-polymerization-curable silicone resin material that gives a silicone resin having a glass transition temperature of 50° C. or less when cured, the addition-polymerization-curable silicone resin material including,
a SiH-group-containing siloxane-based compound containing a SiH group where a silicon atom is bonded to a hydrogen atom,
a C═C-bond-containing siloxane-based compound containing a carbon-carbon double bond capable of effecting addition reaction with the SiH group, and
a hydrosilylation addition reaction catalyst; and
a non-reactive siloxane-based compound that does not react with the SiH-group-containing siloxane-based compound or the C═C-bond-containing siloxane-based compound, that is compatible with the addition-polymerization-curable silicone resin material, and that has a pour point of 0° C. or less;
wherein the electronic element is sealed with the cured product.
